(19) United States
(12) Patent Application Publication
(10) Pub. No.: US 2026/0011570 A1
(43) Pub. Date: Jan. 8, 2026

(54) CHEMICAL ETCH USING SELECTIVE ION IMPLANTATION

(71) Applicant: Tokyo Electron Limited, Tokyo (JP)

(72) Inventor: Akiteru Ko, Albany, NY (US)

(21) Appl. No.: 18/766,272

(22) Filed: Jul. 8, 2024

(51) Int. Cl. H01L 21/3115; H01L 21/311

(52) U.S. Cl. CPC H01L 21/31155; H01L 21/31116

(57) ABSTRACT

A method of chemically etching an underlying material includes selectively modifying the underlying material (e.g., a silicon-containing material, like silicon carbide) using lightweight ions (e.g., hydrogen ions, helium ions, etc.) to form a modified region of the underlying material and chemically etching the modified region using a halogen-containing etchant gas (e.g., a fluorine-containing gas, like sulfur hexafluoride). The underlying material is exposed through openings in a resist layer, which may contain carbon and/or a metal, such as a chemically amplified resist or a metal oxide resist. The selective modification step may implant the lightweight ions into the underlying material. Plasma may be used during one or both of the selective modification step and the chemical etching step. Bias power may be applied during the selective modification step and may be higher than bias power applied during the chemical etching step, which may be zero.

### TECHNICAL FIELD

The present invention relates generally to etching processes, and, in particular embodiments, to systems and methods for chemically etching an underlying material.

### BACKGROUND

Electronic device fabrication (e.g., microelectronic devices fabricated as integrated circuits using semiconductor processing methods) typically involves a series of manufacturing techniques that include formation, patterning, and removal of a number of layers of material on a substrate. Etch masks may be formed (e.g., deposited, grown, patterned) to protect regions of the substrate and allow for pattern transfer via etching. Wet or dry etching processes may be used, with plasma etching processes being an example of a dry etching process. Etching processes that etch dielectric materials are often used to create electrical (e.g., conductive) connections between and within layers.

Etching processes are used in a variety of semiconductor processing areas to form structures in material layers of a substrate, such as by using patterned etch masks. Etch masks may be formed using photolithographic processes by exposing a photoresist layer to structured actinic radiation and developing the photoresist to form a relief pattern. The relief pattern can then be transferred to an underlying layer of the photoresist layer (e.g., an etch-target layer or an underlying hard mask layer formed over an etch-target layer).

As technology advances, feature sizes (i.e., critical dimensions) are reduced and device density increases, requiring mask features to also have smaller dimensionality. For instance, the half pitch of current technology nodes has shrunk to the teens of nanometers while future technology nodes will reach single digits of nanometers (and likely endeavor to become as small as possible). As the lateral dimensions of mask features decrease, the stability of the mask features also decreases, exacerbating interactions between the features of the mask. This can lead to pattern defects such as photoresist line or pillar collapse. To account for this, the height of the mask features is also reduced to maintain or even reduce the aspect ratio of the mask features themselves, resulting in thinner and thinner resist films (e.g., with film thickness <15 nm, such as for high numerical aperture (high-NA) photoresists). Various types of photoresist may be used as a high-NA photoresist, including chemically amplified resist (CAR) and metal-oxide-resist (MOR).

During subsequent etch processes, thinner photoresist films may be excessively damaged or etched away entirely destroying the integrity of the pattern transfer (i.e., there is a low resist budget). Since the ability to increase the thickness of the photoresist film is limited, etching processes seek to improve resist retention in other ways. For example, resist retention can be increased by increasing the selectivity of the etching process (i.e., the ratio of the etch rate of the resist material and the etch rate of the target material). Therefore, etching processes that have improved selectively may be desirable.

### SUMMARY

In accordance with an embodiment of the invention, a method of chemically etching an underlying material includes selectively modifying the underlying material using hydrogen ions to form a modified region of the underlying material and chemically etching the modified region using a halogen-containing etchant gas. The underlying material is exposed through openings in a resist layer.

In accordance with another embodiment of the invention, a method of chemically etching an underlying material includes performing a selective modification step and a chemical etching step. The selective modification step includes exciting a plasma that has hydrogen ions, and exposing both a patterned resist layer and the underlying material of a substrate in a plasma etching chamber to the hydrogen ions to form a modified region in the underlying material. The underlying material is exposed through openings in the patterned resist layer. The chemical etching step includes flowing a halogen-containing etchant gas into the plasma etching chamber, and exciting a plasma from the halogen-containing etchant gas to etch the modified region of the underlying material.

In accordance with still another embodiment of the invention, a plasma etching system includes a plasma etching chamber, a substrate holder disposed in the plasma etching chamber, a hydrogen ion source fluidically coupled to the plasma etching chamber; an etchant gas source fluidically coupled to the plasma etching chamber, a source power supply configured to couple source power to gases in the plasma etching chamber, and a controller operationally coupled the hydrogen ion source, the etchant gas source, and the source power supply. The substrate holder is configured to support a substrate including a patterned resist layer having openings exposing an underlying material. The hydrogen ion source is configured to provide hydrogen ions in the plasma etching chamber. The etchant gas source is configured to supply a halogen-containing etchant gas into the plasma etching chamber.

The controller includes a processor and a non-transitory computer-readable medium storing a program including instructions that, when executed by the processor, perform a method of chemically etching the underlying material by performing a selective modification step and a chemical etching step. The selective modification step includes exciting a plasma that includes the hydrogen ions, and exposing both the patterned resist layer and the underlying material to the hydrogen ions to form a modified region in the underlying material. The chemical etching step includes flowing the halogen-containing etchant gas into the plasma etching chamber, and exciting a plasma from the halogen-containing etchant gas to etch the modified region of the underlying material.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example etching process schematically showing an initial state of a substrate including a resist layer having openings exposing an underlying material, the example etching process including a selective modification step using lightweight ions followed by a chemical etching step using a halogen-containing etchant gas in accordance with embodiments of the invention;

FIG. 2 illustrates a conventional etching process that etches an underlying material using a single etch step with a single etchant gas throughout the conventional etching process;

FIG. 3 illustrates an example etching process schematically showing an initial state of a substrate including a resist layer having openings exposing an underlying material disposed on an obscured material, the example etching process including a selective modification step using a hydrogen plasma followed by a chemical etching step using a in accordance with embodiments of the invention;

FIG. 4 illustrates a conventional etching process that etches an underlying material disposed on an obscured material using a single etch step with a single etchant gas;

FIG. 5 illustrates an example etching process schematically showing a selective modification step that uses lightweight ions to modify a silicon carbide (SiC) underlying material followed by a chemical etching step that uses a halogen-containing etchant gas to chemically etch the modified SiC material in accordance with embodiments of the invention;

FIG. 6 illustrates an example etching process schematically showing a selective modification step that uses lightweight ions to modify a silicon nitride (SiN) underlying material followed by a chemical etching step that uses a halogen-containing etchant gas to chemically etch the modified SiN material in accordance with embodiments of the invention;

FIG. 7 illustrates an example etching process schematically showing a selective modification step that uses lightweight ions to modify a silicon oxycarbide (SiOC) underlying material followed by a chemical etching step that uses a halogen-containing etchant gas to chemically etch the modified SiOC material in accordance with embodiments of the invention;

FIG. 8 illustrates an example plasma etching system that has a plasma etching chamber within which etching processes that include a selective modification step using lightweight ions followed by a chemical etching step using a halogen-containing etchant gas may be performed in situ in accordance with embodiments of the invention;

FIG. 9 illustrates a specific example of a method of chemically etching an underlying material in accordance with embodiments of the invention; and

FIG. 10 illustrates another specific example of a method of chemically etching an underlying material in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

As the pitch (i.e., lateral dimensionality in one or both directions) gets smaller and smaller for patterned resist layers used in electronic device fabrication, the thickness of the resist layer (i.e., vertical dimensionality) gets thinner and thinner. In the past, resist thicknesses were as high as 100 nm or even higher. Resist thicknesses have become much thinner and will continue to decrease in the future. Often the aspect ratio of patterned features (resist thickness divided by half pitch) remain in a certain range even as the dimensionality decreases, such as in the range of about 2 to about 3 (e.g., 2.2., 2.5, 2.8, etc.). For example, current technology employs resist thicknesses of about 35 nm for 16 nm half pitch while future technology will employ 16 nm resist thickness for 8 nm half pitch with additional reductions in resist thickness probable.

One specific motivation for reducing resist thickness is the use of high-NA lithography (e.g., extreme ultraviolet (EUV) lithography using “high” numerical aperture, such as 0.33 and higher). The resist thickness for 0.33 EUV lithography is as low as about 25 nm and becomes lower as the numerical aperture is increased. Photoresists that can meet the demanding requirements of high-NA lithography are used, examples of which include CAR resists and MOR resists, but of course other types may be used.

One effect of a thinner resist layer is to increase the likelihood portions of the patterned resist becoming too thin to protect the underlying material before the end point of an etching process is reached. For instance, a trade-off exists between resist retention and line pinching. Specifically, the resist thickness may be increased to enhance resist retention, but this also leads to a higher probability that structures will interact and collapse causing regions of a line to be “pinched” off. Conversely, when the resist is thinner the resist structures are less likely to collapse, but effects such as variations in resist height (such as those that may occur for spin-on resists) can cause regions of the pattern to be removed before the etching process is completed, which can cause defects such as line breaks. Additionally, little or no margin exists for resist scum removal at lower resist thicknesses.

Various mechanisms may be used to accomplish etching of an underlying material. Two examples of etching mechanisms are chemical etch mechanisms and physical etch mechanisms. One or both may be present during a given etching process. For example, reactive-ion etching (RIE) uses both physical and chemical etch mechanisms. Chemical etch mechanisms are chemical reactions between etchant species and a target material that result in removable by-products (e.g., gas phase species). Consequently, the selectivity of chemical etching mechanisms is based on relative reaction rates of chemical reactions between etchant species and resist materials and chemical reactions between the etchant species and target materials (i.e. an underlying material exposed by openings of the resist layer).

On the other hand, physical etch mechanisms rely on etchant species physically impacting a target material to physically damage the surface of the target material and dislodge removable by-products (i.e., sputtering material from the surface of the target material). The selectivity of physical etch mechanisms may then be based on the kinetic energy (e.g., ion energy) of the etchant species required to sputter resist material compared to that required to sputter the underlying material.

Unlike chemical reactions, which can often be highly (if not infinitely) selective, sputtering damage, sputtering damage often occurs to both the resist material and the underlying material. Higher ion energy may damage the resist material more than lower ion energies. Similarly, heavier species (e.g., including heavier constituent atoms, for example) may also damage the resist material more compared to lighter species since heavier species have more kinetic energy than lighter species at the same speed.

The inventors have discovered that heavier elements, such as argon (Ar) and fluorine (F) have a relatively high sputtering yield on C/CH₂ and Sn compared to lighter species, such as helium (He) and hydrogen (H). For this reason, it may be advantageous to avoid the use of heavier elements in process gases for etching processes when possible. Certain elements and compounds may be common within a given category of resists. For example, CAR resists may be similar in the sense that they include carbon (or more specifically —CH₂— regions, as an example). Meanwhile, MOR resists may have the similarity of including a metal, such as tin (Sn). For this reason, the use of lighter species as opposed to heavier species may be particularly advantageous for CAR and/or MOR resists (but of course the same principle may apply for other resist chemistries).

In accordance with embodiments herein described, the invention proposes an etching process that selectively modifies an underlying material (i.e., a target material of the etching process) that is exposed through openings in a resist layer (i.e., a patterned resist layer disposed over the underlying material). Specifically, the selective modification step modifies the reactivity of the underlying material with respect to an etchant species to form modified regions of the underlying material while limiting or entirely avoiding modification to the resist layer. The etchant species is then introduced to the modified regions to chemically etch the underlying material. That is, the underlying material is etched during the chemical etching step substantially entirely by a chemical etching mechanism (if present at all, other etching mechanisms like physical etching mechanisms are negligible).

The selective modification step uses lightweight ions (e.g., hydrogen ions) to modify the underlying layer. The lightweight ions may be generated in the same chamber as the underlying material (e.g., as part of a plasma treatment) or may be delivered into chamber from an external ion source, like a remote plasma source or an ion implanter (i.e., equipment specially designed for ion implantation). In various embodiments, the selective modification step is an ion implantation step, where the lightweight ions are accelerated towards the underlying layer and remain in the underlying material. For example, velocity may be imparted to the lightweight ions by an electric field, such as substantially in the vertical direction, so that the lightweight ions penetrate some distance into the underlying material. In various embodiments, the lightweight ions are generated from a plasma that is excited in the same chamber as the underlying material and then accelerated toward the underlying material using an electric field induced by a negative bias potential applied to the substrate holder.

The lightweight species may affect the local and global properties of the underlying material so that the modified region exhibits enhanced reactivity towards the etchant species during the chemical etching step. For example, the lightweight ions may selectively introduce defects (e.g., structural, damage, discontinuities, reactive sites, etc.) in underlying material, but not in the resist layer). In some cases, the resist layer is substantially impervious to the lightweight ions (e.g., H⁺ ions) so that the selective modification step has substantially infinite selectivity to the resist material.

The selective nature of the modification step may have the benefit of reducing or eliminating the need for physical etch mechanisms (which may undesirable damage the resist layer). Moreover, appropriate chemistry may be chosen so that the selectivity of the chemical etch mechanism for the underlying material relative to the resist material is as high as possible (e.g., substantially infinite in some cases). The improved etch selectivity may in turn enable the use of a “gentle” plasma (i.e., a plasma with lower energy that has a reduced chance of undesirably damaging the resist layer, such as by sputtering). One example is a gentle plasma containing fluorine radicals (F*), such as a plasma excited from sulfur hexafluoride gas (SF₆), or a plasma excited from nitrogen trifluoride gas (NF₃), among others. In some cases, the achieved ultra-high selectivity may allow gas-phase etching of the underlying material.

The increased selectivity during the chemical etching step afforded by interactions with the lightweight ions is also substantially localized to regions of the underlying layer that are vertically aligned with the openings in the resist layer. This may have additional benefits, such as relaxing requirements on the verticality of etchant species. For example, the overall effect of the chemical etching step may be a directional etch into the underlying material through the openings. However, the chemical etch mechanism that is leveraged to etch the underlying material may have little or no inherent directionality (as may be common with purely chemical etches). Instead the net directionality may be indirectly obtained from the vertical nature of the lightweight ions used during the selective modification step.

In some applications, it may be considered advantageous to be able to perform the two-step etching process in situ in the same processing chamber (i.e., in place without relocating the substrate containing the underlying material). For example, in a specific example of the etching process where the selective modification step uses a plasma excited in the same processing chamber as the plasma used to etch the underlying layer in the chemical etching step, the etch tool (i.e., the plasma etching apparatus, plasma etching system, etc.) may be improved relative to conventional etch tools or equipment designed to achieve similar results (but with more complicated and/or expensive methodologies).

Because the etch selectivity is increased by the selective modification step in combination with the chemical etching step, the rate at which resist layer is consumed is reduced (or even becomes substantially zero) allowing the resist layer to be made thinner for a given etching application. This may have the benefit of making the etching processes described herein suitable for use in current and future technologies requiring thin resist, such as those utilizing high-NA resists (e.g., CAR resists, MOR resists, and others).

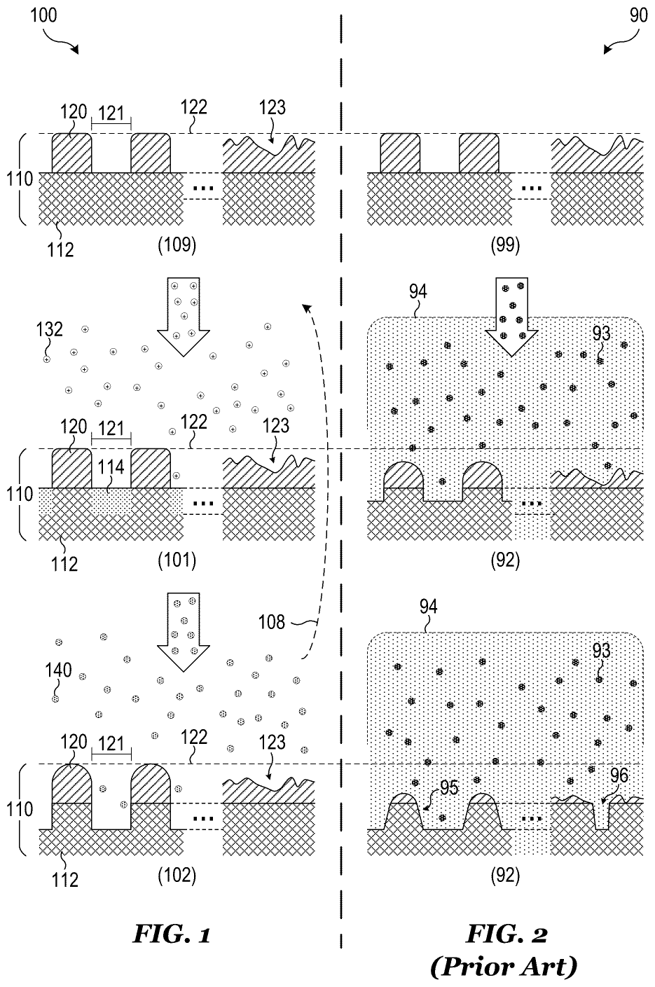

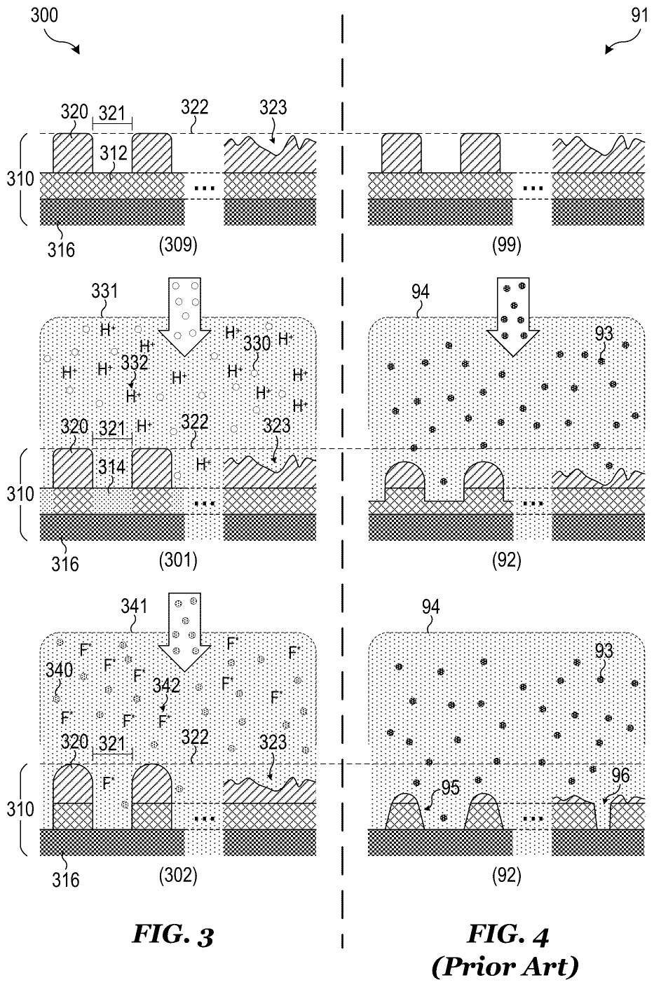

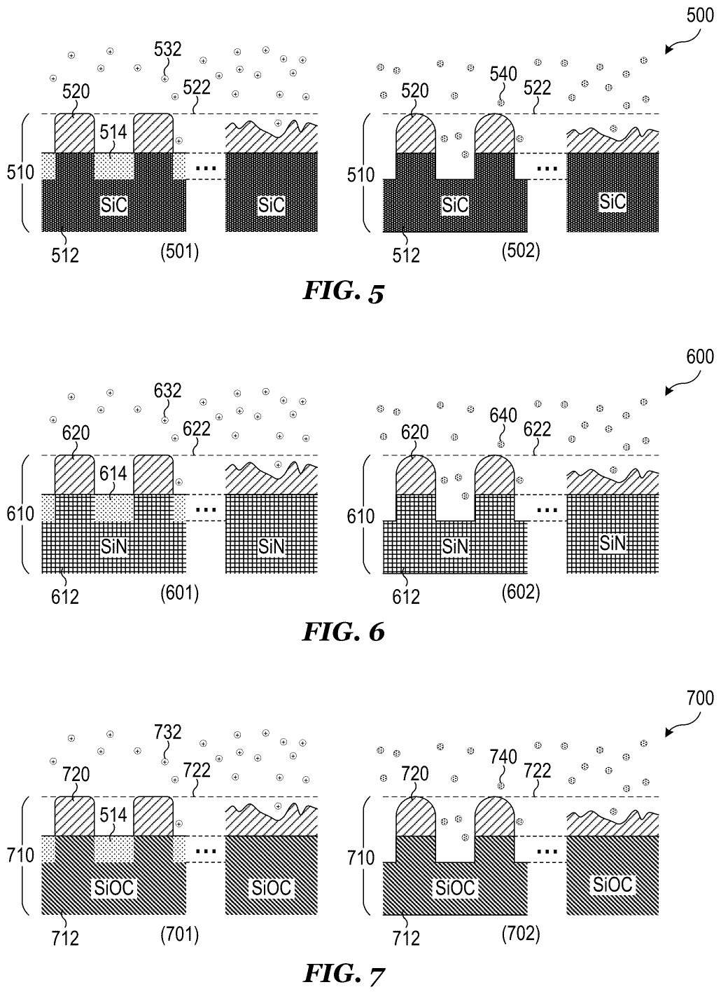

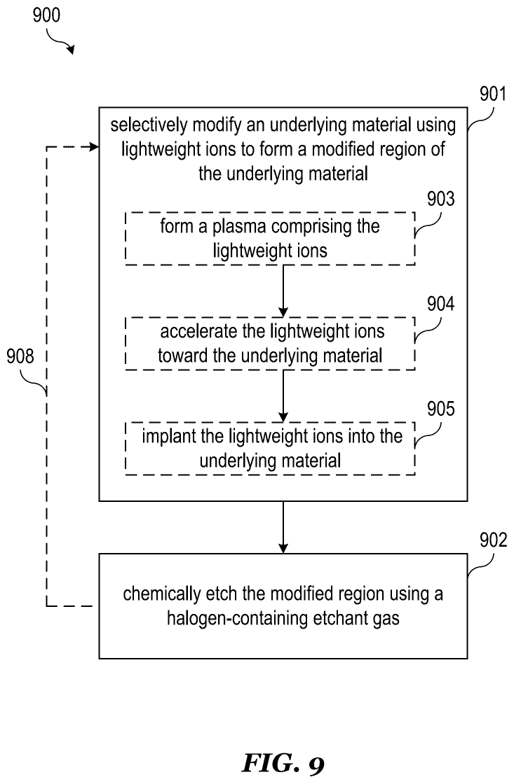

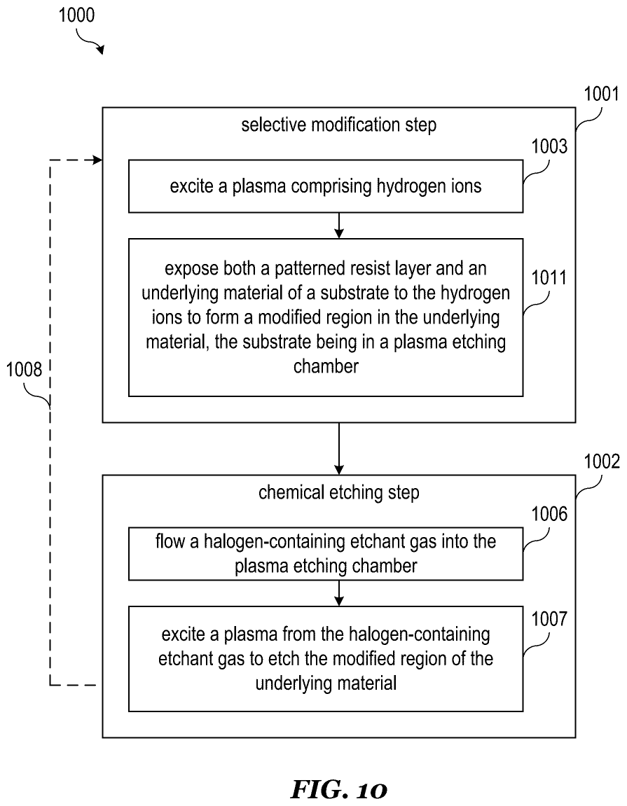

Embodiments provided below describe various methods and systems for chemically etching an underlying material, and in particular embodiments, to systems and methods for chemically etching an underlying material that include a selective modification step using lightweight ions followed by a chemical etching step using a halogen-containing etchant gas. The following description describes the embodiments. FIG. 1 is used to describe an example etching process that is compared to a conventional etching process shown in FIG. 2. FIG. 3 is used to describe a more specific example etching process that is also compared to a conventional etching process shown in FIG. 4. Three more example etching processes are described using FIGS. 5-7. An example plasma etching system that may be used to perform etching processes and methods is described using FIG. 8. Two specific example methods are described using FIGS. 9 and 10.

FIG. 1 illustrates an example etching process schematically showing an initial state of a substrate including a resist layer having openings exposing an underlying material, the example etching process including a selective modification step using lightweight ions followed by a chemical etching step using a halogen-containing etchant gas in accordance with embodiments of the invention. For comparison purposes, FIG. 2 is also provided alongside and illustrates a conventional etching process that etches an underlying material using a single etch step with a single etchant gas throughout the conventional etching process. For example, the example etching process of FIG. 1 may have increased etch selectivity that advantageously results in improved resist retention and profile compared to the conventional etching process of FIG. 2, as shown.

Referring to FIG. 1, an etching process 100 includes both a selective modification step 101 and a chemical etching step 102 that are used together to chemically etch an underlying material 112. An initial state 109 of a substrate 110 containing the underlying material 112 is shown. For example, when the substrate 110 is in the initial state 109, the substrate 110 may be located in a processing chamber (e.g., supported by a substrate holder in a plasma etching chamber). A resist layer 120 is disposed over the underlying material 112 so that openings 121 in the resist layer 120 expose surfaces of the underlying material 112 and the resist layer 120 may be used as a mask during the etching process 100 (e.g., a patterned resist layer used as an etch mask). The underlying material 112 may be any underlying layer, and is a transfer layer in some embodiments.

At the initial state 109, the resist layer 120 may be at an initial resist height 122. Some areas of the substrate 110 may have substantially uniform structures at or very near the initial resist height 122, such as schematically depicted at the left side of the initial state 109. However, other areas of the substrate 110 may exhibit some degree of resist height variation resulting in regions of uneven resist 123, as shown at the right of the initial state 109. Such height variation may decrease the resist budget since low points in the uneven resist 123 may expose undesirable regions the underlying material 112 during an etching process if the resist is too thin.

In the selective modification step 101, lightweight ions 132 (e.g., H⁺) are provided at the substrate 110 and are incident with exposed surfaces of both the resist layer 120 and the underlying material 112. When the lightweight ions 132 interact with the underlying material 112, a modified region 114 is formed (e.g., an altered region, materially, chemically, structurally, or a combination thereof, such as an implanted region, damage region, etc.), whereas any interactions of the lightweight ions 132 with the resist layer 120 do not result in significant modification. In various embodiments, the lightweight ions 132 are accelerated toward the substrate 110 and, in some embodiments, are implanted into the underlying material 112 (but not the resist layer 120 or at least any implantation does not increase the reactivity of the resist layer 120 to a subsequent etching step).

The lightweight ions 132 may be generated as part of a plasma excited in the same chamber as the substrate 110 (as part of a plasma treatment, for example), but this does not have to be the case. For example, in other embodiments, the lightweight ions 132 are generated elsewhere (e.g., in a remote plasma source, an ion implanter, etc.) and then introduced into the chamber containing the substrate 110. In various embodiments, the lightweight ions 132 are hydrogen ions (H⁺) that are generated in a plasma excited from hydrogen gas (H₂). Of course, the lightweight ions 132 may also be other ionic species (helium ions, (He⁺), lithium ions (Li⁺), etc., depending on the specific chemistry of the selective modification step 101 and the chemical etching step 102).

Implantation of the lightweight ions 132 into the underlying material 112 may be performed using various techniques. For example, in various embodiments, implantation is accomplished by accelerating the lightweight ions 132 toward the substrate within the same chamber as the substrate 110, such as by using an electric field in the processing chamber. In one embodiment, the lightweight ions 132 are generated in a plasma and accelerated toward the substrate 110 in the same chamber as the substrate 110 (e.g., a processing chamber, such as a plasma etching chamber). In other embodiments, the lightweight ions 132 are accelerated before reaching the processing chamber, such as within an ion implanter, a remote plasma chamber, or using ion optics between these or other ion sources. When formed by an external source, the lightweight ions 132 may be accelerated both externally and within the processing chamber in some embodiments.

The lightweight ions 132 may be generated by excited a pure gas (e.g., an H₂ gas to generate H⁺ ions, etc.). This may have the advantage of producing only the desired ions (mixed in some proportion with the pure gas) without producing additional unwanted species. However, the lightweight ions 132 may also be produced by a gas source that includes additional unwanted species, such as by ionizing a more complex compound and filtering out lighter/heavier species to before the lightweight ions 132 are provided into the processing chamber (e.g., in an ion filter of an ion implanter).

During the chemical etching step 102, a halogen-containing etchant gas 140 is provide at the substrate 110 (e.g., flowed into the processing chamber). The modified region 114 is selectively etched by the halogen-containing etchant gas 140 while little to no material is removed from the resist layer 120. In various embodiments, a plasma may be generated from the halogen-containing etchant gas 140 (such as to form halogen ions and/or radicals, like F*). The plasma may be a “gentle” plasma, with low ion energy. That is, plasma species (e.g., radicals) generated from the halogen-containing etchant gas 140 may be used to etch the underlying material 112, but species of the gentle plasma have sufficiently low energy to avoid significant contribution from physical etch mechanisms (and therefore may have the advantage of avoiding sputtering of the resist layer 120). In some embodiments, the halogen-containing etchant gas 140 may be in the gas phase during the chemical etching step 102.

Advantageously, the net effect of the etching process 100 may still be directional due to the highly selective nature of the chemical reaction that etches the modified region 114 (both relative to the resist layer 120 and to the unmodified regions of the underlying material 112). In particular, the directionality of the selective modification step 101 may be utilized to provide a vertical profile of the modified region 114 (e.g., using the vertical nature of the lightweight ions 132 accelerated to implant into the underlying material 112). The enhanced reactivity of the modified region 114 towards the halogen-containing etchant gas 140 may then allow the modified region 114 (with the vertical profile) to be selectively etched relative to both the resist layer 120 and the unmodified regions of the underlying material 112 by low-energy ions or gas phase etchant species.

When plasma is employed during the chemical etching step 102, source power may be coupled to the halogen-containing etchant gas 140 to generate the plasma (e.g., RF power, in the high frequency (HF) range, very high frequency (VHF) range, microwave (MW) range, or any suitable frequency range). The source power may be coupled to the halogen-containing etchant gas 140 using any desired mechanism including capacitive coupling, inductive coupling, and others. An electric field may be induced to accelerate etchant ions to toward the substrate 110, such as using bias power applied to a substrate holder supporting the substrate 110 (whether radio frequency (RF) power, direct current (DC) power, RF power with a DC offset, pulsed RF, pulsed DC, or any combination thereof). In various embodiments where bias power is used, the bias power in the chemical etching step 102 is less than the bias power used during the selective modification step 101 (in some cases much less or even zero).

The halogen-containing etchant gas 140 may include various halogens, such as F (fluorine), chlorine (Cl), bromine (Br), etc. In some cases, the halogen-containing etchant gas 140 may include more than one halogen-containing species, such as a fluorine source and a bromine source. When a plasma is excited from the halogen-containing etchant gas 140 various plasma species may be formed, including ions and neutral radicals of the halogen, such as F* and F⁺ from F, for example. During the chemical etching step 102, the etching mechanism is substantially a chemical etch mechanism including chemical reactions between the halogen-containing etchant gas 140 and/or plasma species generated therefrom and the modified region 114 of the underlying material 112, such as between the neutral radicals.

In various embodiments, the halogen-containing etchant gas 140 includes a fluorine-containing gas. In some embodiments, the halogen-containing etchant gas 140 includes a chlorine-containing gas. In one embodiment, the halogen-containing etchant gas 140 includes sulfur hexafluoride (SF₆), but other fluorine-containing gases may also be used, such as nitrogen trifluoride (NF₃), tungsten hexafluoride (WF₆), and others. However, in some cases it may be advantageous to avoid introducing certain species (such as metals) into the processing chamber, such as to avoid contaminating materials of the substrate 110.

The material compositions of the resist layer 120, the underlying material 112, the lightweight ions 132, and the halogen-containing etchant gas 140 may be chosen based on the details of a given application. Specifically, the interactions between these compounds are configured to facilitate selective modification of the underlying material 112 and also selectively etch the modified region 114 (while doing little or no damage to the resist layer 120 during both steps).

In various embodiments, the resist layer 120 comprises carbon and the resist layer 120 comprises —CH₂— bonds in some embodiments. In one embodiment, the resist layer 120 is a CAR resist. In various embodiments, the resist layer 120 comprises a metal and the resist layer 120 comprises Sn in one embodiment. Other possible metals include hafnium (Hf), zirconium (Zr), and others. In one embodiment, the resist layer 120 is an MOR resist. In some cases, the resist layer 120 may include both carbon and a metal, such as when the resist layer 120 includes an organometallic compound, such as an organotin compound, for example.

The underlying material 112 may be any material configured to be selectively modified by the lightweight ions 132 in the selective modification step 101 to form a modified region 114 (the lateral extent of which is dictated by the openings 121 of the resist layer 120) that is selectively chemically etched by the halogen-containing etchant gas 140. In various embodiments, the underlying material 112 includes silicon. In some embodiments, the underlying material 112 includes carbon, and is SiC (silicon carbide) in one embodiment. In some embodiments, the underlying material 112 includes nitrogen and is silicon nitride (SIN) in one embodiment.

Some silicon-containing materials may have bonding structures that are resistant to the lightweight ions 132 of the selective modification step 101 and/or the halogen-containing etchant gas 140 of the chemical etching step 102. For example, in the specific case of using H⁺ ions as the lightweight ions 132, silicon-containing materials that have Si—C or Si—N bonds (e.g., SiC, SiN) may be susceptible to forming a modified region 114 while Si—O bonds may be resistant (e.g., silicon oxide, SiO₂). However, oxygen may still be included in some cases. For instance, in one embodiment, the underlying material 112 is SiOC (silicon oxycarbide). In another embodiment, the underlying material 112 is SiON (silicon oxynitride).

In some embodiments, the selective modification step 101 and the chemical etching step 102 are repeated as part of a cycle 108 to continue etching the underlying material 112. That is, after the chemical etching step 102, the underlying material 112 may be etched to a certain depth (e.g., on the order of nanometers, for example). The selective modification step 101 may be repeated to form a new modified region deeper in the underlying material 112 and the etching may be continued using the chemical etching step 102. In this way, the etching process 100 may be performed as a cyclic process (e.g., in situ in the same processing chamber) to etch the underlying material 112 to the desired depth (which may be to a deeper layer, obscured by the underlying material 112).

For comparison, FIG. 2 shows a conventional etching process 90 that uses a single etch step 92 where a conventional etching plasma 94 is formed using a single etchant gas 93. A substrate in a conventional initial state 99 is shown as being similar to the initial state 109 for comparison. However, when the single etch step 92 is applied to the substrate in the conventional initial state 99, the conventional etching plasma 94 excited from the single etchant gas 93 etches the resist layer along with the underlying material (i.e., the selectivity of the conventional etching process 90 is lower than that of the etching process 100) and the height of resist layer decreases faster relative to the initial resist height 122 than in the etching process 100. As a result, the remaining material of the resist layer becomes insufficient to protect the underlying material before the conventional etching process 90 is completed leading to a poor etch profile 95. Additionally, variation in the resist height leads to defects 96 caused by regions of the resist layer being etched away entirely.

FIG. 3 illustrates an example etching process schematically showing an initial state of a substrate including a resist layer having openings exposing an underlying material disposed on an obscured material, the example etching process including a selective modification step using a hydrogen plasma followed by a chemical etching step using a in accordance with embodiments of the invention. The etching process of FIG. 3 may be a specific implementation of other etching processes described herein such as the etching process of FIG. 1, for example. Similarly labeled elements may be as previously described.

For comparison purposes, FIG. 4 is also provided alongside and illustrates a conventional etching process that etches an underlying material disposed on an obscured material using a single etch step with a single etchant gas. For example, the example etching process of FIG. 3 may have increased etch selectivity that advantageously results in improved resist retention and profile compared to the conventional etching process of FIG. 4, as shown.

Referring to FIG. 3, an etching process 300 includes both a selective modification step 301 and a chemical etching step 302 that are used together to chemically etch an underlying material 312. It should be noted that here and in the following a convention has been adopted for brevity and clarity wherein elements adhering to the pattern [x01] where ‘x’ is the figure number may be related implementations of a selective modification step in various embodiments. For example, the selective modification step 301 may be similar to the selective modification step 101 except as otherwise stated. An analogous convention has also been adopted for other elements as made clear by the use of similar terms in conjunction with the aforementioned numbering system.

An initial state 309 of a substrate 310 containing the underlying material 312 is shown. A resist layer 320 at an initial resist height 322 and with schematically depicted uneven resist 323 regions is disposed over the underlying material 312 so that openings 321 in the resist layer 320 expose surfaces of the underlying material 312. The substrate 310 also includes an obscured material 316 that is covered (i.e., obscured) by the underlying material 312. The obscured material 316 may be any suitable material, such as a material into which a pattern is transferred using the etched underlying material 312 as a transfer layer.

In the selective modification step 301, hydrogen ions 332 are provided at the substrate 310 to form a modified region 314 whereas any interactions of the hydrogen ions 332 with the resist layer 320 do not result in significant modification. In this specific implementation, the hydrogen ions 332 are accelerated toward the substrate 310 (e.g., using an applied bias power during the selective modification step 301). The hydrogen ions 332 are generated as part of a hydrogen plasma 331 excited in the same chamber as the substrate 310 from a hydrogen gas 330 (e.g., H₂).

During the chemical etching step 302, a fluorine-containing etchant gas 340 is provide at the substrate 310 and the modified region 314 is selectively etched using the fluorine-containing etchant gas 340. In this specific example, a halogen-containing plasma 341 is excited from the fluorine-containing etchant gas 340 to form a halogen-containing plasma 341. In various embodiments, the predominant etch mechanism during the chemical etching step 302 is a chemical etch mechanism, such as by fluorine radicals (F*), for example.

Bias power may also be applied during the chemical etching step 302 to provide a desired degree of ion energy and/or verticality to the ions in the halogen-containing plasma 341. For example, as noted above, the chemical etching step 302 is substantially a chemical etch, so ion energy may be kept low (e.g., the halogen-containing plasma 341 may be a gentle plasma). Therefore, in various embodiments, the bias power applied during the chemical etching step 302 is lower than the bias power applied during the selective modification step 301, and the bias power during the chemical etching step 302 is zero in one embodiment.

In this specific embodiment, the selective modification step 301 and the chemical etching step 302 result in exposing the obscured material 316 through the openings 321 in the resist layer 320. However, in some cases, the selective modification step 301 and the chemical etching step 302 are repeated as part of a cycle to iteratively remove portions of the underlying material 312 to reach the obscured material 316. That is, a few nanometers of the underlying material 312 may be removed each time with very high selectivity allowing the obscured material 316 to be reached with minimal or no damage to the resist layer 320.

For comparison, FIG. 4 shows a conventional etching process 91 that uses the single etch step 92 where the conventional etching plasma 94 is formed using the single etchant gas 93. Similar to before, a substrate in the conventional initial state 99 (now showing an obscured layer) is shown as being similar to the initial state 309 for comparison. When the single etch step 92 is applied to the substrate the result is that the remaining material of the resist layer becomes insufficient to protect the underlying material before the conventional etching process 91 is completed leading to the poor etch profile 95. Additionally, variation in the resist height leads to defects 96 caused by regions of the resist layer being etched away entirely that expose the obscured layer.

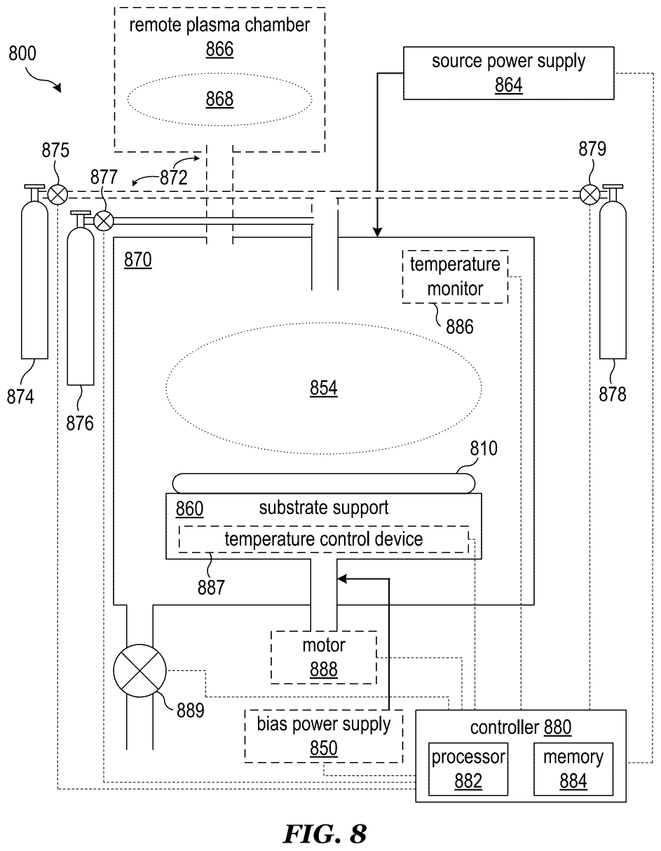

FIGS. 5-7 illustrate an example etching process schematically showing a selective modification step that uses lightweight ions to modify specific examples of underlying materials in accordance with embodiments of the invention. In particular, FIG. 5 illustrates a selective modification step that modifies an SiC (silicon carbide) underlying material, FIG. 6 illustrates a selective modification step that modifies an SiN (silicon nitride) underlying material, and FIG. 7 illustrates a selective modification step that modifies an SiOC (silicon oxycarbide) underlying material. Similarly labeled elements may be as previously described.

Referring to FIG. 5, an etching process 500 includes both a selective modification step 501 and a chemical etching step 502 that are used together to chemically etch an underlying material 512 of a substrate 510 through a resist layer 520. In this specific example, the underlying material 512 is substantially SiC (silicon carbide, which may be a combination of silicon and carbon in some stoichiometric configuration that may vary throughout the material). The resist layer 520 is at an initial resist height 522 and is disposed over the underlying material 512. In the selective modification step 501, lightweight ions 532 are provided at the substrate 510 to form a modified region 514 in the SiC material. The modified SiC material is then etched using a halogen-containing etchant gas 540 in the chemical etching step 502.

Now referring to FIG. 6, an etching process 600 includes both a selective modification step 601 and a chemical etching step 602 that are used together to chemically etch an underlying material 612 of a substrate 610 through a resist layer 620. In this specific example, the underlying material 612 is substantially SiN (silicon nitride, which may be a combination of silicon and nitrogen in some stoichiometric configuration that may vary throughout the material). The resist layer 620 is at an initial resist height 622 and is disposed over the underlying material 612. In the selective modification step 601, lightweight ions 632 are provided at the substrate 610 to form a modified region 614 in the SiN material. The modified SiN material is then etched using a halogen-containing etchant gas 640 in the chemical etching step 602.

Turning to FIG. 7, an etching process 700 includes both a selective modification step 701 and a chemical etching step 702 that are used together to chemically etch an underlying material 712 of a substrate 710 through a resist layer 720. In this specific example, the underlying material 712 is substantially SiOC (silicon oxycarbide, which may be a combination of silicon, oxygen, and carbon in some stoichiometric configuration that may vary throughout the material). The resist layer 720 is at an initial resist height 722 and is disposed over the underlying material 712. In the selective modification step 701, lightweight ions 732 are provided at the substrate 710 to form a modified region 714 in the SiOC material. The modified SiOC material is then etched using a halogen-containing etchant gas 740 in the chemical etching step 702. Of course, the underlying material 712 may also be other materials. One analogous example may be an underlying material that is substantially SiON (silicon oxynitride).

FIG. 8 illustrates an example plasma etching system that has a plasma etching chamber within which etching processes that include a selective modification step using lightweight ions followed by a chemical etching step using a halogen-containing etchant gas may be performed in situ in accordance with embodiments of the invention. The plasma etching system of FIG. 8 may be used to perform any of the methods and processes described herein such as any of the etching processes of FIGS. 1-7 and the methods of FIGS. 9 and 10, for example. Similarly labeled elements may be as previously described.

Referring to FIG. 8, a plasma etching system 800 (i.e., a specific example of a processing system that is configured to etch a target material, such as an underlying material, using plasma) includes a substrate holder 860 disposed within a plasma etching chamber 870 (a specific example of a processing chamber) and configured to support a substrate 810. For example, the substrate 810 may include a patterned resist layer having openings exposing the underlying material. A lightweight ion source 872 (e.g., a hydrogen ion source) is fluidically coupled to the plasma etching chamber 870 and is configured to supply lightweight ions (e.g., hydrogen ions) to the plasma etching chamber 870 (whether indirectly or directly).

For example, the lightweight ion source 872 may be a lightweight gas source 874 fluidically coupled to the plasma etching chamber 870 through a lightweight gas valve 875, such as a gas source that supplies a lightweight gas (e.g., H₂ gas) into the plasma etching chamber 870 from which lightweight ions (e.g., H⁺ ions) may be generated, (e.g., by igniting a plasma from the lightweight gas). Alternatively, the lightweight ion source 872 may optionally be a remote ion source, such as a remote plasma chamber 866 configured to generate a remote plasma 868 containing lightweight ions. In implementations that use a remote ion source, the remote plasma chamber 866 may generate the ions for extraction into the plasma etching chamber 870 or the optional remote plasma chamber 866 may be part of an ion implanter.

An etchant gas source 876 is fluidically coupled to the plasma etching chamber 870 through an etchant gas valve 877. For example, the etchant gas source 876 may be a gas source or sources that includes a gas, such as a halogen-containing gas, configured to etch an underlying material. Additional gas sources and valves may also be included in the plasma etching system 800. For example, an optional additional gas source 878 (e.g., a gas source or sources including additional gases, which may be any type of gas, such as carrier gases, additional reactants and precursors, stabilizers, catalysts and others) may be fluidically coupled to the plasma etching chamber 870 through an optional additional gas valve 879. An exhaust valve 889 is also included to evacuate the plasma etching chamber 870 during the processes performed therein, such as process steps including selective modification steps and chemical etching steps as described herein, as well as other process steps.

The plasma etching system 800 is configured to generate plasma 854 during some or all steps of an etching process. Specifically, a source power supply 864 is configured to couple source power to gases within the plasma etching chamber 870 in order to generate the plasma 854 (which may be plasma formed from the etchant gas during a chemical etching step and may be plasma formed from the lightweight gas, when used, during a selective modification step). The plasma etching chamber 870 may be any suitable etching chamber, such as a capacitively coupled plasma (CCP) etching chamber, an inductively coupled plasma (ICP) etching chamber, etc.

A bias power supply 850 may also be included that is configured to supply (e.g., couple) bias power to the substrate holder 860 (and the substrate 810), such as to accelerate ions in the plasma 854 towards the substrate 810, for example. As previously described, the bias power may be higher during a selective modification step to accelerated lightweight ions towards the substrate 810 and lower (or even zero) during a chemical etching step since the chemical process may not rely on high-energy ions to etch the modified regions of an underlying material.

An optional temperature monitor 886 may also be included to monitor and/or aid in controlling the temperature of the substrate 810 and the environment in the plasma etching chamber 870. An optional temperature control device 887 may be included to raise or lower the temperature of the substrate 810 above or below the equilibrium temperature at the substrate 810 during the etching processes. Alternatively, the optional temperature control device 887 may be a cooler to decrease the temperature of the substrate 810 below equilibrium. An optional motor 888 may also be included to improve uniformity of some processes.

A controller 880 is operatively coupled to source power supply 864, lightweight ion source 872 (e.g., the remote plasma chamber 866 or the lightweight gas valve 875), and the etchant gas valve 877, and may be operatively coupled to the exhaust valve 889. The controller 880 may also be operatively coupled to any of the optional additional gas valve 879, the optional bias power supply 850, the optional temperature monitor 886, the optional temperature control device 887, and the optional motor 888 (e.g., when one or more are included). For example, the controller 880 is configured to flow various gases into the plasma etching chamber 870 with desired timing to perform the etching processes.

The controller 880 includes a processor 882 and a memory 884 (i.e., a non-transitory computer-readable medium) that stores a program including instructions that, when executed by the processor 882, perform processes such as the etching processes described herein. For example, the memory 884 may have volatile memory (e.g., random access memory (RAM)) and non-volatile memory (e.g., flash memory). Alternatively, the program may be stored in physical memory at a remote location, such as in cloud storage. The processor 882 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 9 illustrates a specific example of a method of chemically etching an underlying material in accordance with embodiments of the invention. The method of FIG. 9 may be combined with other methods and performed using the systems and apparatuses as described herein. For example, the method of FIG. 9 may be combined with any of the embodiments of FIGS. 1-8 and 10. Although shown in a logical order, the arrangement and numbering of the steps of FIG. 9 are not intended to be limited. The method steps of FIG. 9 may be performed in any suitable order or concurrently with one another as may be apparent to a person of skill in the art

Referring to FIG. 9, a method 900 of chemically etching an underlying material includes a selective modification step 901 of selectively modifying the underlying material using lightweight ions (e.g., hydrogen ions) to form a modified region of the underlying material. The underlying material is exposed through openings in a resist layer (e.g., a photoresist, such as a CAR resist, an MOR resist, etc.). The underlying layer may be any desired material, some examples of which include Si, SiC, SIN, SiOC, and SiON, to name a few. The modified region is then etched in a chemical etching step 902 using a halogen-containing etchant gas (e.g., a fluorine-containing gas, such as SF₆ or NF₃). In various embodiments, the selective modification step 901 and the chemical etching step 902 may be repeated as part of a cycle 908 to further etch the underlying material.

The selective modification step 901 may be accomplished in a variety of ways. In one embodiment, the selective modification step 901 includes a plasma formation step 903 during which a plasma (e.g., a hydrogen plasma) comprising the lightweight ions is formed (e.g., in the processing chamber that includes a substrate with the underlying material, such as a plasma etching chamber, or externally, such as in a remote plasma chamber). In other embodiments, other ion source mechanisms may be used, such as thermionic emission, chemical ionization, etc.

In one embodiment, the selective modification step 901 includes an ion acceleration step 904 during which the lightweight ions are accelerated toward the underlying material. For example, the lightweight ions may be accelerated in the processing chamber using an induced electric field (e.g., by applying bias power to a substrate holder supporting the substrate). The lightweight ions may also be accelerated externally (e.g., using ion optics, such as with an ion implanter).

In one embodiment, an selective modification step 901 includes the ion implantation step 905 during which the lightweight ions are implanted into the underlying material. For example, the ion acceleration step 904, when included, may accelerate the lightweight ions to a sufficient velocity to allow the lightweight ions to be implanted into the underlying material. That is, the ion acceleration step 904 may in some cases not result in implantation, but may be implemented in such a way as to accomplish the ion implantation step 905. Further, the plasma formation step 903 may also be performed along with the ion acceleration step 904 and/or the ion implantation step 905. It is, of course also possible that the lightweight ion source produces ions that already possess sufficient kinetic energy for implantation so that the ion acceleration step 904 is not needed even when the ion implantation step 905 is included.

FIG. 10 illustrates another specific example of a method of chemically etching an underlying material in accordance with embodiments of the invention. The method of FIG. 10 may be combined with other methods and performed using the systems and apparatuses as described herein. For example, the method of FIG. 9 may be combined with any of the embodiments of FIGS. 1-9. Although shown in a logical order, the arrangement and numbering of the steps of FIG. 10 are not intended to be limited. The method steps of FIG. 10 may be performed in any suitable order or concurrently with one another as may be apparent to a person of skill in the art.

Referring to FIG. 10, a method 1000 of chemically etching an underlying material includes a selective modification step 1001 and a chemical etching step 1002, which may be repeated as part of a cycle 1008 to continue etching the underlying material. The selective modification step 1001 includes a plasma formation step 1003 during which a plasma comprising hydrogen ions is excited, and an exposure step 1011 (e.g., implantation via ion bombardment, a plasma treatment, or both) where a patterned resist layer (e.g., including carbon and/or a metal, such as a CAR resist, a MOR resist, or another type of resist) and the underlying material (e.g., a target material, such as a transfer layer including silicon) of a substrate is exposed to the hydrogen ions to form a modified region in the underlying material. The underlying material may include specific bond types, such as Si-C bonds or Si—N bonds. The substrate is located in a plasma etching chamber and the underlying material is exposed through openings in the patterned resist layer.

The chemical etching step 1002 includes an etchant flowing step 1006 to flow a halogen-containing etchant gas into the plasma etching chamber and an etch plasma formation step 1007 during which a plasma is excited from the halogen-containing etchant gas to etch the modified region of the underlying material. The halogen-containing etchant gas may include any suitable halogen, such as F, Cl, Br, etc. For example, the halogen-containing etchant gas may be a fluorine-containing gas, such as SF₆, NF₃, etc.

The selective modification step 1001 may further include applying a first bias power to a substrate holder supporting the substrate to accelerate the hydrogen ions toward the substrate and applying a second bias power to the substrate holder, the second bias power being less than the first bias power. Additionally, the plasma with the hydrogen ions may be excited by flowing a hydrogen gas into the plasma etching chamber, and exciting a plasma from the hydrogen gas in the plasma etching chamber. Alternatively, the plasma may be excited in a remote plasma chamber (i.e., that is fluidically coupled to the plasma etching chamber).

The cycle 1008 may include repeatedly performing the selective modification step 1001 to form additional modified regions in the underlying material, and the chemical etching step 1002 to continue etching the underlying material. For example, the cycle 1008 may be continued until a desired etch depth into the underlying material is achieved, which may be exposing an obscured layer (such as when the underlying material is a configured to be a transfer layer for transferring the pattern to the obscured layer in a subsequent process).

Example embodiments of the invention are summarized here. Other embodiments can also be understood from the entirety of the specification as well as the claims filed herein.

Example 1. A method of chemically etching an underlying material, the method including: selectively modifying the underlying material using hydrogen ions to form a modified region of the underlying material, the underlying material being exposed through openings in a resist layer; and chemically etching the modified region using a halogen-containing etchant gas.

Example 2. The method of example 1, where selectively modifying the underlying material includes implanting the hydrogen ions into the underlying material by accelerating the hydrogen ions toward the underlying material.

Example 3. The method of one of examples 1 and 2, where selectively modifying the underlying material includes forming a hydrogen plasma including the hydrogen ions.

Example 4. The method of example 3, wherein forming the hydrogen plasma comprises exciting a pure hydrogen gas (H₂).

Example 5. The method of one of examples 1 to 4, where the resist layer is a CAR layer or a MOR layer.

Example 6. The method of one of examples 1 to 5, where the underlying material is substantially Si, SiC, SiN, SiOC, or SiON.

Example 7. The method of one of examples 1 to 6, where the halogen-containing etchant gas includes SF₆ gas or NF₃ gas.

Example 8. A method of chemically etching an underlying material, the method including: performing a selective modification step including exciting a plasma including hydrogen ions, and exposing both a patterned resist layer and the underlying material of a substrate in a plasma etching chamber to the hydrogen ions to form a modified region in the underlying material, the underlying material being exposed through openings in the patterned resist layer; and performing a chemical etching step including flowing a halogen-containing etchant gas into the plasma etching chamber, and exciting a plasma from the halogen-containing etchant gas to etch the modified region of the underlying material.

Example 9. The method of example 8, where the selective modification step further includes applying a first bias power to a substrate holder supporting the substrate to accelerate the hydrogen ions toward the substrate, and where the chemical etching step further includes applying a second bias power to the substrate holder, the second bias power being less than the first bias power.

Example 10. The method of one of examples 8 and 9, where exciting the plasma including the hydrogen ions includes flowing a hydrogen gas into the plasma etching chamber, and exciting a plasma from the hydrogen gas in the plasma etching chamber.

Example 11. The method of one of examples 8 and 9, where exciting the plasma including the hydrogen ions includes exciting the plasma including the hydrogen ions in a remote plasma chamber fluidically coupled to the plasma etching chamber.

Example 12. The method of one of examples 8 to 11, where the patterned resist layer includes carbon.

Example 13. The method of one of examples 8 to 12, where the patterned resist layer includes a metal.

Example 14. The method of one of examples 8 to 13, where the underlying material includes silicon.

Example 15. The method of example 14, where the underlying material includes silicon-carbon bonds or silicon-nitrogen bonds.

Example 16. The method of one of examples 8 to 15, where the halogen-containing etchant gas includes fluorine.

Example 17. The method of one of examples 8 to 16, further including: performing a cycle after performing the chemical etching step, the cycle including repeatedly performing the selective modification step to form additional modified regions in the underlying material, and the chemical etching step to continue etching the underlying material.

Example 18. A plasma etching system including: a plasma etching chamber; a substrate holder disposed in the plasma etching chamber and configured to support a substrate including a patterned resist layer having openings exposing an underlying material; a hydrogen ion source fluidically coupled to the plasma etching chamber and configured to provide hydrogen ions in the plasma etching chamber; an etchant gas source fluidically coupled to the plasma etching chamber and configured to supply a halogen-containing etchant gas into the plasma etching chamber; a source power supply configured to couple source power to gases in the plasma etching chamber; and a controller operationally coupled the hydrogen ion source, the etchant gas source, and the source power supply, the controller including a processor and a non-transitory computer-readable medium storing a program including instructions that, when executed by the processor, perform a method of chemically etching the underlying material by performing a selective modification step including exciting a plasma including the hydrogen ions, and exposing both the patterned resist layer and the underlying material to the hydrogen ions to form a modified region in the underlying material, and a chemical etching step including flowing the halogen-containing etchant gas into the plasma etching chamber, and exciting a plasma from the halogen-containing etchant gas to etch the modified region of the underlying material.

Example 19. The plasma etching system of example 18, further including: a bias power source configured to couple bias power the substrate holder; where the selective modification step further includes applying a first bias power to the substrate holder to accelerate the hydrogen ions toward the substrate; and where the chemical etching step further includes applying a second bias power to the substrate holder, the second bias power being less than the first bias power.

Example 20. The plasma etching system of one of examples 18 and 19, where the hydrogen ion source includes: a hydrogen gas source fluidically coupled to the plasma etching chamber and configured to supply a hydrogen gas to the plasma etching chamber, where exciting the plasma including the hydrogen ions includes flowing the hydrogen gas into the plasma etching chamber, and exciting a plasma from the hydrogen gas in the plasma etching chamber.

Example 21. The plasma etching system of one of examples 18 to 20, where the hydrogen ion source includes: a remote plasma chamber fluidically coupled to the plasma etching chamber; and a hydrogen gas source fluidically coupled to the remote plasma chamber and configured to supply a hydrogen gas to the remote plasma chamber, where exciting the plasma including the hydrogen ions includes flowing the hydrogen gas into the remote plasma chamber, and exciting the plasma from the hydrogen gas in the remote plasma chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of chemically etching an underlying material, the method comprising:
selectively modifying the underlying material using hydrogen ions to form a modified region of the underlying material, the underlying material being exposed through openings in a resist layer; and
chemically etching the modified region using a halogen-containing etchant gas.

2. The method of claim 1, wherein selectively modifying the underlying material comprises implanting the hydrogen ions into the underlying material by accelerating the hydrogen ions toward the underlying material.

3. The method of claim 1, wherein selectively modifying the underlying material comprises forming a hydrogen plasma comprising the hydrogen ions.

4. The method of claim 3, wherein forming the hydrogen plasma comprises exciting a pure hydrogen gas (H₂).

5. The method of claim 1, wherein the resist layer is a chemically amplified resist (CAR) layer or a metal oxide resist (MOR) layer.

6. The method of claim 1, wherein the underlying material is substantially silicon (Si), silicon carbide (SiC), silicon nitride (SiN), silicon oxycarbide (SiOC), or silicon oxynitride (SiON).

7. The method of claim 1, wherein the halogen-containing etchant gas comprises sulfur hexafluoride (SF₆) gas or nitrogen trifluoride (NF₃) gas.

8. A method of chemically etching an underlying material, the method comprising:
performing a selective modification step comprising
exciting a plasma comprising hydrogen ions, and
exposing both a patterned resist layer and the underlying material of a substrate in a plasma etching chamber to the hydrogen ions to form a modified region in the underlying material, the underlying material being exposed through openings in the patterned resist layer; and
performing a chemical etching step comprising
flowing a halogen-containing etchant gas into the plasma etching chamber, and
exciting a plasma from the halogen-containing etchant gas to etch the modified region of the underlying material.

9. The method of claim 8,
wherein the selective modification step further comprises
applying a first bias power to a substrate holder supporting the substrate to accelerate the hydrogen ions toward the substrate, and
wherein the chemical etching step further comprises
applying a second bias power to the substrate holder, the second bias power being less than the first bias power.

10. The method of claim 8, wherein exciting the plasma comprising the hydrogen ions comprises
flowing a hydrogen gas into the plasma etching chamber, and
exciting a plasma from the hydrogen gas in the plasma etching chamber.

11. The method of claim 8, wherein exciting the plasma comprising the hydrogen ions comprises exciting the plasma comprising the hydrogen ions in a remote plasma chamber fluidically coupled to the plasma etching chamber.

12. The method of claim 8, wherein the patterned resist layer comprises carbon.

13. The method of claim 8, wherein the patterned resist layer comprises a metal.

14. The method of claim 8, wherein the underlying material comprises silicon.

15. The method of claim 14, wherein the underlying material comprises silicon-carbon bonds or silicon-nitrogen bonds.

16. The method of claim 7, further comprising:
performing a cycle after performing the chemical etching step, the cycle comprising repeatedly performing the selective modification step to form additional modified regions in the underlying material, and the chemical etching step to continue etching the underlying material.

17. A plasma etching system comprising:
a plasma etching chamber;
a substrate holder disposed in the plasma etching chamber and configured to support a substrate comprising a patterned resist layer having openings exposing an underlying material;
a hydrogen ion source fluidically coupled to the plasma etching chamber and configured to provide hydrogen ions in the plasma etching chamber;
an etchant gas source fluidically coupled to the plasma etching chamber and configured to supply a halogen-containing etchant gas into the plasma etching chamber;
a source power supply configured to couple source power to gases in the plasma etching chamber; and
a controller operationally coupled the hydrogen ion source, the etchant gas source, and the source power supply, the controller comprising a processor and a non-transitory computer-readable medium storing a program including instructions that, when executed by the processor, perform a method of chemically etching the underlying material by performing
a selective modification step comprising exciting a plasma comprising the hydrogen ions, and exposing both the patterned resist layer and the underlying material to the hydrogen ions to form a modified region in the underlying material, and
a chemical etching step comprising flowing the halogen-containing etchant gas into the plasma etching chamber, and exciting a plasma from the halogen-containing etchant gas to etch the modified region of the underlying material.

18. The plasma etching system of claim 17, further comprising:
a bias power source configured to couple bias power the substrate holder;
wherein the selective modification step further comprises applying a first bias power to the substrate holder to accelerate the hydrogen ions toward the substrate; and
wherein the chemical etching step further comprises applying a second bias power to the substrate holder, the second bias power being less than the first bias power.

19. The plasma etching system of claim 17, wherein the hydrogen ion source comprises:
a hydrogen gas source fluidically coupled to the plasma etching chamber and configured to supply a hydrogen gas to the plasma etching chamber,
wherein exciting the plasma comprising the hydrogen ions comprises flowing the hydrogen gas into the plasma etching chamber, and exciting a plasma from the hydrogen gas in the plasma etching chamber.

20. The plasma etching system of claim 17, wherein the hydrogen ion source comprises:
a remote plasma chamber fluidically coupled to the plasma etching chamber; and
a hydrogen gas source fluidically coupled to the remote plasma chamber and configured to supply a hydrogen gas to the remote plasma chamber,
wherein exciting the plasma comprising the hydrogen ions comprises flowing the hydrogen gas into the remote plasma chamber, and exciting the plasma from the hydrogen gas in the remote plasma chamber.
